(19) United States
(12) Patent Application Publication
(10) Pub. No.: US 2018/0175845 A1
(43) Pub. Date: Jun. 21, 2018

(54) DRIVE CIRCUIT FOR SWITCHING ELEMENT

(71) Applicant: Mitsubishi Electric Corporation, Tokyo (JP)

(72) Inventors: Yoshio UEOKA, Tokyo (JP); Yoshitomo HAYASHI, Tokyo (JP)

(73) Assignee: Mitsubishi Electric Corporation, Tokyo (JP)

(21) Appl. No.: 15/126,019

(22) PCT Filed: Nov. 28, 2014
(86) PCT No.: PCT/JP2014/081631

§ 371 Date: Sep. 14, 2016

(51) Int. Cl. H03K 17/0412; H02M 1/08; H03H 7/01; H02M 7/48; H03K 17/16

(52) U.S. Cl. CPC H03K 17/04123; H02M 1/08; H03H 7/0153; H02M 2001/0064; H03K 17/163; H03K 17/168; H02M 7/48

(57) ABSTRACT

A drive circuit for a switching element according to the present embodiment includes a drive-voltage generation circuit that generates a driving voltage for a switching element; and a filter circuit that filters the driving voltage. The filter circuit forms a circuit having a step response represented by a second-order transfer function together with an internal gate resistor and an input capacitor between a gate terminal and an emitter terminal of the switching element. The circuit has a circuit constant that is set to make an attenuation coefficient of the transfer function be a value within a certain range.

### FIELD

The present invention relates to a drive circuit for a switching element that executes drive control targeted at a switching element. The type of switching element can include an IGBT (Insulated Gate Bipolar Transistor) and a FET (Field Effect Transistor).

### BACKGROUND

In recent years, motor controllers have become indispensable because of the widespread use of inverter devices for operating motors at variable speeds. A motor controller includes a power conversion device that converts DC power into AC power or AC power into DC power. The power conversion device uses a switching element such as an IGBT or a MOSFET (Metal-Oxide-Semiconductor FET) and achieves power conversion with the switching element.

The drive circuit for a switching element includes only a gate resistor for V_{GE} charging of the switching element to perform switching of the switching element.

Switching of the switching element described above is controlled and driven by accumulating or releasing charge in or from a gate terminal in order to charge or discharge a gate-emitter voltage. At that time, however, switching loss occurs due to a gate current I_{G} or a collector current I_{C} and EMI (Electro Magnetic Interference) noise simultaneously occurs due to the current changing rate di/dt, which depends on the charging time. The switching loss adversely affects peripheral devices as well as the drive circuit itself.

In order to solve the problem described above, a conventional drive circuit for a switching element is configured to have a circuit for adjusting the switching speed. The switching speed is reduced by this circuit so that any sudden rise of the gate current I_{G} or the collector current I_{C} is suppressed, and thus the EMI noise is reduced. However, the disadvantage of this operation is the trade-off relation wherein as the switching speed is reduced, the loss in the miller period increases, which means making adjustments is difficult.

To solve the problems described above, a drive circuit that adjusts the ON/OFF switching timing of a gate (see Patent Literature 1, for example) and a constant-current drive circuit that causes a constant gate current to continuously flow through a gate terminal (see Patent Literature 2, for example) are proposed.

### CITATION LIST

### Patent Literatures

Patent Literature 1: Japanese Patent Application Laid-open No. 2004-253582 (page 1, FIG. 1)

Patent Literature 2: Japanese Patent No. 4954290 (page 13, FIG. 8)

### SUMMARY

### Technical Problem

The invention of Patent Literature 1 described above has a problem in that a plurality of drive circuits are provided and the ON/OFF timings of the gates in the respective drive circuits need to be adjusted. In the invention in Patent Literature 2, the switching loss can be decreased without increasing the current changing rate di/dt. However, there is a problem in that the loss in the miller period is increased because the gate current is caused to continuously flow for a certain time. Furthermore, the inventions described in Patent Literatures 1 and 2 require a complicated circuit and the drive circuit is increased in size due to the increase in the number of constituent parts.

The present invention has been achieved in view of the above problems, and an objective of the present invention is to provide a drive circuit for a switching element that can reduce switching loss and EMI noise while avoiding the need for the drive circuit to have a complicated configuration.

### Solution to Problem

In order to solve the problem and to achieve the objective mentioned above, the present invention relates to a drive circuit for a switching element that includes a drive-voltage generation circuit that generates a driving voltage for a switching element; and a filter circuit that filters the driving voltage. The filter circuit forms a circuit having a step response represented by a second-order transfer function together with an internal gate resistor of the switching element and an input capacitor between a gate terminal and an emitter terminal of the switching element. The circuit has a circuit constant that is set to make an attenuation coefficient of the transfer function be a value within a certain range.

### Advantageous Effects of Invention

The drive circuit for a switching element according to the present invention can reduce switching loss and EMI noise while avoiding the need for the drive circuit to have a complicated circuit configuration.

### BRIEF DESCRIPTION OF DRAWINGS

FIG. 1 is a diagram illustrating an example configuration of a drive circuit for a switching element.

FIG. 2 is a diagram illustrating a drive circuit for a switching element when the input capacitor between the gate and the emitter of the switching element is being charged.

FIG. 3 is a diagram illustrating the drive circuit for a switching element in a miller period.

FIG. 4 is a diagram illustrating an example configuration of a drive circuit for a switching element in a case where the filter circuit is an RC filter.

FIG. 5 are explanatory diagrams of an operation of the drive circuit for a switching element.

FIG. 6 is a diagram illustrating an example of step responses of a gate voltage.

### DESCRIPTION OF EMBODIMENTS

Exemplary embodiments of a drive circuit for a switching element according to the present invention will be explained below in detail with reference to the accompanying drawings. The present invention is not limited to the embodiments.

### EMBODIMENT

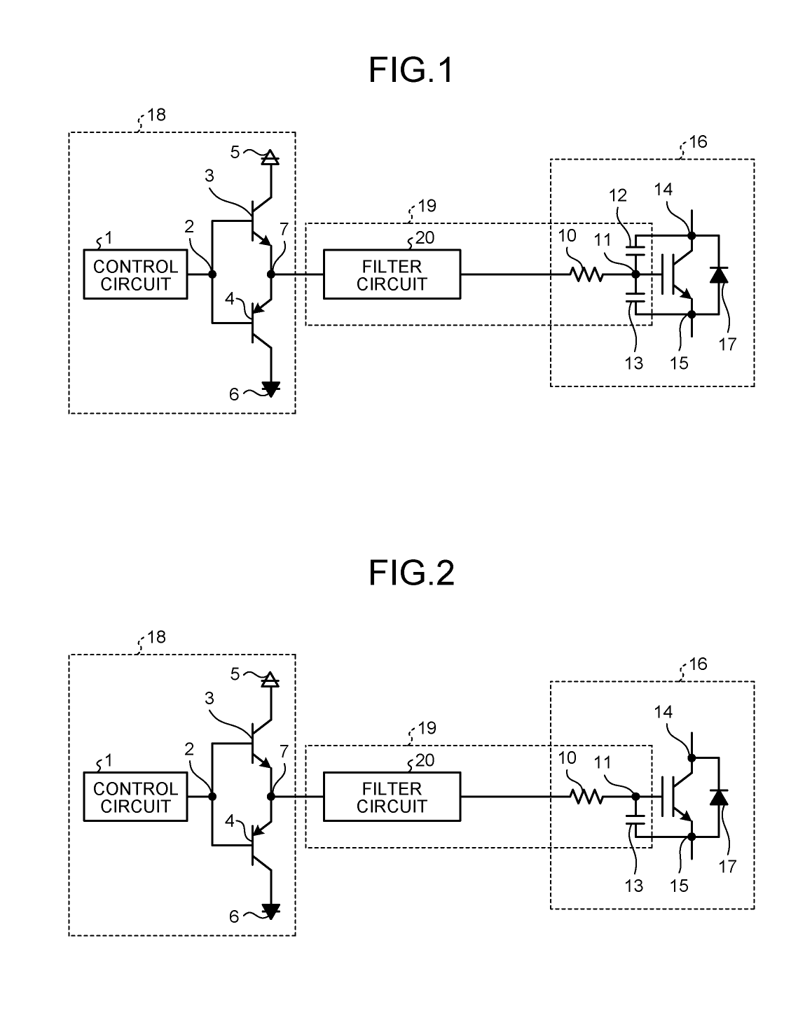

FIG. 1 is a diagram illustrating an example of the circuit configuration of a drive circuit for a switching element according to the present invention. The drive circuit for a switching element (hereinafter, simply “drive circuit”) according to an embodiment of the present invention is a circuit that controls a switching element 16 that is a target. Further, the drive circuit includes a control circuit 1, switches 3 and 4, and a filter circuit 20. The switching element 16 is, for example, a power semiconductor element such as an IGBT or a FET. The switching element 16 has a feedback diode 17 connected between a collector 14 and an emitter 15. The switching element 16 also has an internal gate resistor 10, an input capacitor (C_{gc}) 12 between a gate 11 and the collector 14, and an input capacitor (C_{ge}) 13 between the gate 11 and the emitter 15. The switching element 16 is applied to, for example, a power conversion device such as an inverter.

The control circuit 1 determines whether the switching element 16 is ON or OFF and generates a voltage command (V_{ref}) 2 corresponding to the determined result. The switch 3 is, for example, an NPN transistor and the switch 4 is, for example, a PNP transistor. Bases and emitters of the switches 3 and 4 are connected to each other, and the voltage command V_{ref} 2 is input to both of the bases. The collector of the switch 3 is connected to a positive power source 5 (a positive electrode of a switching-element driving power source (not illustrated)) and the collector of the switch 4 is connected to a negative power source 6 (a negative electrode of the switching-element driving power source (not illustrated)). Together with the control circuit 1, these switches 3 and 4 form a drive-voltage generation circuit 18 that generates a gate voltage 7 that is the driving voltage for the switching element 16 and outputs the generated gate voltage 7. The gate voltage 7 is generated in accordance with the voltage command V_{ref}, which is a pulse signal input from the control circuit 1. For example, when the voltage command V_{ref} is ON (at a level designating ON for the switching element 16), the switch 3 is turned ON and the switch 4 is turned OFF so as to output the potential of the positive power source 5 as the gate voltage 7. When the voltage command V_{ref} is OFF (at a level designating OFF for the switching element 16), the switch 3 is turned OFF and the switch 4 is turned ON so as to output the potential of the negative power source 6 as the gate voltage 7. The gate voltage 7 is applied to the gate 11 of the switching element 16 via the filter circuit 20. The gate voltage 7 charges the input capacitor (C_{ge}) 13 between the gate 11 and the emitter 15 of the switching element 16 and the input capacitor (C_{gc}) 12 between the gate 11 and the collector 14 of the switching element 16 so as to cause there to be a conductive state between the collector 14 and the emitter 15.

FIG. 2 is a diagram illustrating a drive circuit when driving of the switching element 16 is started. When driving of the switching element 16 is started, i.e., when a positive gate voltage 7 (the potential of the positive power source 5) is applied to the gate 11, the input capacitor C_{ge} 13 of the switching element 16 is first charged with the gate voltage 7 as illustrated in FIG. 2. Charging of the input capacitor C_{ge} 13 is performed until voltages on both ends of the input capacitor C_{ge} 13 exceed a threshold voltage at which a collector current starts flowing from the collector 14 to the emitter 15.

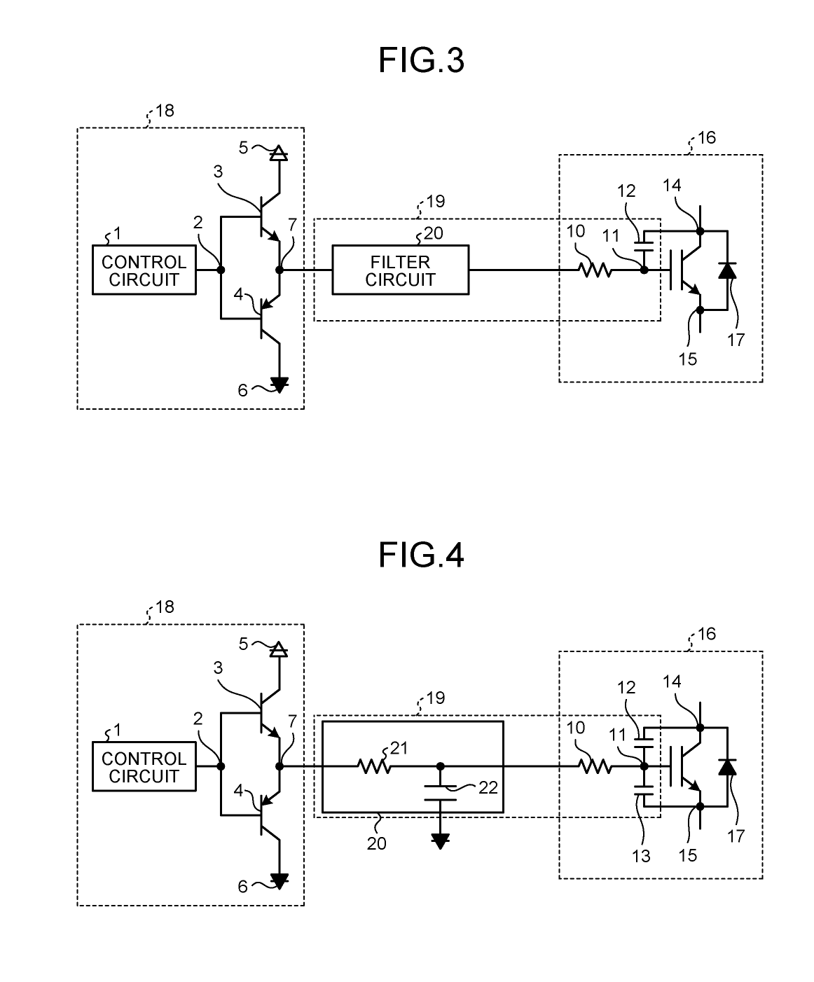

FIG. 3 is a diagram illustrating a drive circuit in a miller period after the charging of the input capacitor C_{ge} 13 described above ends. In the miller period after the charging of the input capacitor C_{ge} 13 ends, the flow of the gate current I_{G} into the gate 11 of the switching element 16 becomes constant and a voltage V_{ce} between the collector 14 and the emitter 15 gradually decreases.

In the drive circuit configured as described above, the internal gate resistor 10 and the input capacitor C_{ge} 13 of the switching element 16 and the filter circuit 20 are considered as one block 19 so that this block 19 can be handled as a transfer function from the voltage command V_{ref} to the gate 11 of the switching element 16.

In this example, because the internal gate resistor 10 and the input capacitor C_{ge} 13 of the switching element 16 form a filter, the circuit of the block 19 has a configuration in which filters are connected in series.

The filter circuit 20 is an RC filter including a resistor 21 and a capacitor 22 as illustrated, for example, in FIG. 4.

In the drive circuit configured as illustrated in FIG. 4, a step response of the block 19 can be expressed by a second-order lag transfer function and can be represented by the following general expression (expression (1)).

G(s)=ωₙ²/(s₂+2ζωₙs+ωₙ²) (1)

A peak value of the gate current can be adjusted by adjusting the attenuation coefficient ζ. That is, the EMI noise can be reduced by adjusting the attenuation coefficient ζ so as to set the peak value of the gate current smaller. Furthermore, by configuring the circuit of the block 19 so as to include the filter circuit 20, i.e., configuring the circuit of the block 19 so as to have a step response expressed by a second-order lag transfer function, the gate current value in the miller period can be set larger than that in a conventional drive circuit that does not include the filter circuit 20. When the gate current value in the miller period is increased, the miller period is shortened and thus a reduction in switching loss can be realized. It is preferable that the attenuation coefficient ζ described above satisfies 0.7≤ζ≤1.0. By setting the attenuation coefficient ζ to have a value included in the above range, the EMI noise and the switching noise can be reduced when compared to those of the conventional drive circuit. For this reason, the filter circuit 20 is configured to fall within the coefficient ζ range described above.

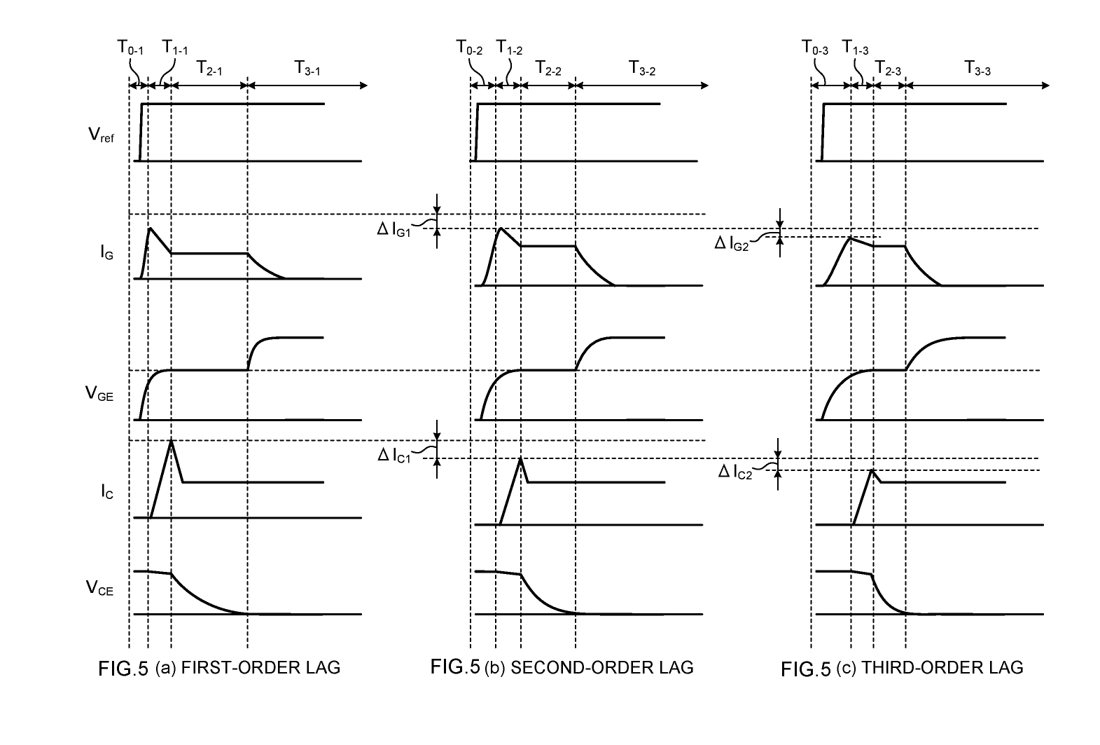

The voltage command (V_{ref}) 2 and the gate voltage 7 are supplied as pulses. An operation in response to a step input, when set ON, is described for both a case where the present embodiment is applied and a case where the present embodiment is not applied. Each step response in a case where the filter circuit 20 is included (the case where the present embodiment is applied) and a case where the filter circuit 20 is not included is illustrated in FIG. 5.

FIG. 5 are explanatory diagrams of an operation of the drive circuit according to the present embodiment and are timing charts illustrating examples of voltage waveforms and current waveforms of constituent parts of the drive circuit and the switching element 16. The horizontal axis represents the time and the vertical axis represents the voltage value or the current value. FIG. 5(a) illustrates a timing chart of a circuit not including the filter circuit 20, which corresponds to a conventional drive circuit (hereinafter, “conventional circuit”), and FIGS. 5(b) and 5(c) illustrate timing charts of the drive circuit according to the present embodiment. FIG. 5(b) is a timing chart in a case where the filter circuit 20 is configured as illustrated in FIG. 4. FIG. 5(c) is a timing chart in a case where the filter circuit 20 is configured to include two stages of RC filters in series, in which each RC filter includes the resistor 21 and the capacitor 22 illustrated in FIG. 4. When two stages of the RC filters are included in series, the step response of the circuit of the block 19 is expressed by a third-order lag transfer function. In the conventional circuit not including the filter circuit 20, a circuit corresponding to the block 19 includes a gate resistor and a step response thereof is expressed by a first-order lag transfer function. Hereinafter, for convenience of description, the drive circuit having the configuration illustrated in FIG. 4 is referred to as a “second-order lag drive circuit”; and the drive circuit including the filter circuit 20 configured to include two stages of the RC filters in series, in which each RC filter includes the resistor 21 and the capacitor 22 illustrated in FIG. 4, is referred to as a “third-order lag drive circuit”.

A third-order lag transfer function that gives the step response illustrated in FIG. 5(c) is described below.

The third-order lag transfer function G(s) is represented by the following expression (2).

$$\begin{matrix}[ Expression 1 ] & \\ G ( s ) = \frac{{k}_{p} \cdot {k}_{p 1} \cdot {k}_{p 2}}{{s}^{3} + {k}_{p 2} \cdot {s}^{2} + {k}_{p 1} \cdot {k}_{p 2} \cdot s + {k}_{p} \cdot {k}_{p 1} \cdot {k}_{p 2}} & ( 2 )\end{matrix}$$

A general expression of a third-order lag transfer function G(s) is given by the following expression (3)

$$\begin{matrix}[ Expression 2 ] & \\ G ( s ) = \frac{{P}_{r} \cdot {ω}_{n}^{2}}{( s + {P}_{r} ) \cdot ( {s}^{2} + 2 ζ \cdot {ω}_{n} \cdot s + {ω}_{n}^{2} )} & ( 3 )\end{matrix}$$

In the case of a drive circuit having a step response represented by the expression (3), it is known that no overshoot generally occurs when the condition is true such that Pᵣ is smaller relative to a real part of a conjugate complex number of S₂+2·ζ·ωₙ+ωₙ². Therefore, a condition in which no overshoot occurs is given by the following expression (4) and a marginal condition in which no overshoot occurs is given by the following expression (5).

Pᵣ≤ζ·ωₙ (4)

Pᵣ=ζ·ωₙ (5)

On the basis of the expressions (2) to (5) described above, a parameter that causes no overshoot is given by the following expression (6).

[Expression 3]

kₚ·kₚ₁·kₚ₂≤ζ·ω³

kₚ₁·kₚ₂≤(2·ζ²+1)·ωₙ²

kₚ₂≤3·ζ·ωₙ (6)

When ζ and ωₙ are eliminated from the expression (6), the following expression (7) is obtained.

[Expression 4]

2kₚ₂²−9·kₚ₁·kₚ₂+27·kₚ·kₚ₁≥0 (7)

By setting kₚ₁ and kₚ₂ so as to satisfy the above expression (7), a drive circuit for a third-order lag causing no overshoot is obtained.

As also described in the descriptions of the second-order lag transfer function, it is preferable that the attenuation coefficient ζ satisfies 0.7≤ζ≤1.0. Therefore, it is preferable that the attenuation coefficient ζ of a third-order lag transfer function satisfies 0.7≤ζ≤Pᵣ/ωₙ. The limit value ζ that causes no overshoot in the case of a second-order lag is 1 (ζ=1), which corresponds to Pᵣ/ωₙ in the case of a third-order lag (ζ=Pᵣ/ωₙ).

In FIG. 5, V_{ref} denotes an output (a voltage command) from the control circuit 1 illustrated in FIG. 4; I_{G} denotes a gate current flowing in the input capacitors C_{gc} 12 and C_{ge} 13 of the switching element 16; V_{GE} denotes a voltage with which the input capacitor C_{ge} 13 is charged; I_{C} denotes a current flowing from the collector 14 to the emitter 15 in the switching element 16; and V_{CE} denotes a voltage between the collector 14 and the emitter 15.

As illustrated in FIG. 5, in all drive circuits including the conventional circuit, when the gate voltage 7 (a potential of the positive power source 5) designating that the switching element 16 is ON is applied in a period T₀ (that is, periods T₀₋₁, T₀₋₂, and T₀₋₃), the gate current I_{G} starts flowing from the gate 11 of the switching element 16 to the input capacitor C_{ge} 13 so as to accumulate charges therein. When the voltage V_{GE} to which the input capacitor C_{ge} 13 is charged thereafter exceeds the ON voltage of the switching element 16, the collector current I_{C} starts flowing (periods T₁₋₁, T₁₋₂, and T₁₋₃). When the collector current I_{c} reaches a peak, the period T₁ (the periods T₁₋₁, T₁₋₂, and T₁₋₃) ends and a period T₂ (periods T₂₋₁, T₂₋₂, and T₂₋₃), which is a miller period, starts. In the period T₂, the voltage V_{GE} and the gate current I_{G} become constant due to the miller effect of the switching element 16. Meanwhile, the voltage V_{CE} gradually decreases. In a period T₃ (periods T₃₋₁, T₃₋₂, and T₃₋₃) after the miller period (the period T₂) has passed, the gate current I_{G} gradually decreases while the voltage V_{GE} increases. Accordingly, it is more preferable that the period T₁ is shorter so as to increase the switching speed. However, if the period T₁ is too short, the peak values of the gate current I_{G} and the collector current I_{C} become large, which increases the EMI noise. However, with the drive circuit including the filter circuit 20, the gate current value in the miller period can be increased while the overshoot of the gate current I_{G} and the collector current I_{C} is reduced due to the transfer characteristics of the block 19 including the filter circuit 20. As illustrated in FIG. 5, for example, in the case of the second-order lag drive circuit, the peak value of the gate current I_{G} can be reduced by ΔI_{G1} and also the peak value of the collector current I_{C} can be reduced by ΔI_{C1} when compared to those in the conventional circuit (a first-order lag). In the case of the third-order lag drive circuit, the peak value of the gate current I_{G} can be reduced by ΔI_{G1}+ΔI_{G2} and also the peak value of the collector current I_{C} can be reduced by ΔI_{C1}+ΔI_{C2} when compared to those in the conventional circuit.

A reason that provision of the filter circuit 20 can reduce the peak value and increase the gate current value in the miller period is described here.

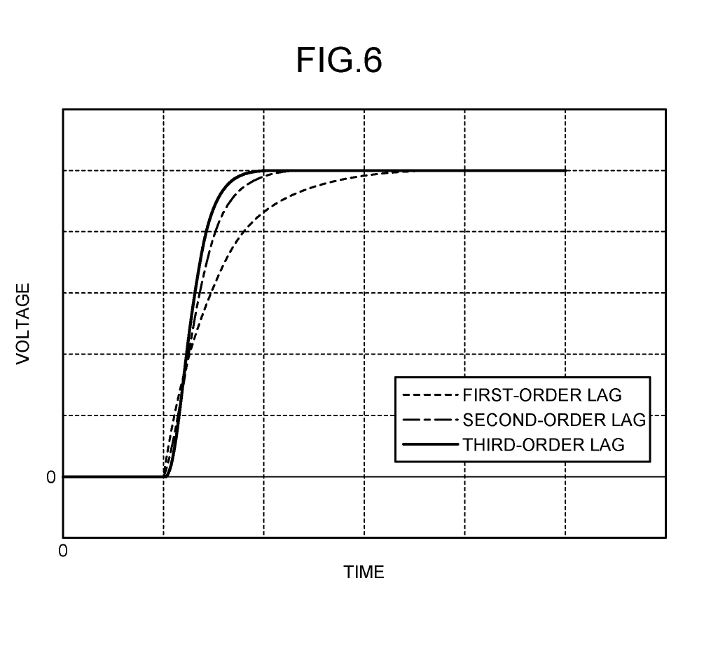

FIG. 6 is a diagram illustrating an example of step responses of the gate voltage 7 in the cases where the step responses of the circuit of the block 19 are a first-order lag, a second-order lag, and a third-order lag, respectively. The horizontal axis represents the time and the vertical axis represents the voltage applied to the gate 11 of the switching element 16. The dashed line indicates the step response of a first-order lag, i.e., in the conventional circuit; the dashed-dotted line indicates the step response in a second-order lag drive circuit; and the solid line indicates the step response in a third-order lag drive circuit. As illustrated in FIG. 6, immediately after an input of the gate voltage 7 is started, the voltage applied to the gate 11 of the switching element 16 rises more gently in the second-order lag drive circuit and the third-order lag drive circuit than in the conventional circuit. Accordingly, as illustrated in FIG. 5, the gate current I_{G} rises more gently, and consequently the peak value is suppressed and thus is low, and thus the EMI noise is reduced. As illustrated in FIG. 6, as the order is higher, the voltage rises more gently. The time required to reach a target voltage is shorter in the second-order lag drive circuit and the third-order lag drive circuit than in the conventional circuit. Therefore, the time required to charge the input capacitors 12 and 13 is also shortened and switching loss can be reduced. As the order becomes higher, the time required to reach the target voltage becomes shorter.

Furthermore, with a reduction in the peak value of the gate current I_{G}, the gate resistor, which is the resistance of the resistor 21 illustrated in FIG. 4, can be reduced and the loss in the gate resistor can be reduced. Because the gate current I_{G} in the miller period is increased by reducing the gate resistor, the miller period can be shortened and the loss in the miller period can be reduced.

In the present embodiment, a circuit in which the resistor 21 is inserted in series with the switching element 16 and in which the capacitor 22 is inserted in parallel therewith is used as the filter circuit 20. However, the present embodiment is not limited thereto. Furthermore, two elements are not always required. A filter circuit including an inductor can alternatively be used. The filter circuit can be configured as an increased number of resistors, capacitors, or the like to provide a higher-order filter circuit, i.e., transfer characteristics of a fourth or higher order lag.

In this manner, an RC filter and other various kind of filters can be applied as the filter circuit 20.

While the switching element 16 is an IGBT or an FET in the present embodiment, the present embodiment is not limited thereto. The material thereof is not limited to Si. A switching element having a wide bandgap, such as typically a SoC, can be used.

As described above, the drive circuit for a switching element according to the present embodiment includes the drive-voltage generation circuit 18 that generates the gate voltage 7 to be applied to the gate 11 of the switching element 16; and the filter circuit 20 placed between the drive-voltage generation circuit 18 and the switching element 16. The filter circuit 20 forms a circuit having transfer characteristics represented by a second-order lag transfer function, a third-order lag transfer function, or a higher-order lag transfer function, together with a filter configured from the internal gate resistor 10 and the input capacitor C_{ge} 13 of the switching element 16. The filter circuit 20 is configured to have an attenuation coefficient of the transfer function falling within a certain range. Accordingly, a drive circuit for a switching element that can reduce switching loss and EMI noise while avoiding the need for the drive circuit to have a complicated configuration can be realized.

### INDUSTRIAL APPLICABILITY

As described above, the drive circuit for a switching element according to the present invention can be widely used for devices that use a switching element, e.g., an inverter device.

### REFERENCE SIGNS LIST

1 control circuit, 2 voltage command (V_{ref}), 3, 4 switch, 5 positive power source, 6 negative power source, 7 gate voltage, 10 internal gate resistor, 11 gate, 12, 13 input capacitor, 14 collector, 15 emitter, switching element, 17 feedback diode, 18 drive-voltage generation circuit, 19 block that constitutes filter, 20 filter circuit, 21 resistor, 22 capacitor.

1. A drive circuit for a switching element, the drive circuit comprising:
a drive-voltage generation circuit that generates a driving voltage for a switching element; and
a filter circuit that forms a circuit having a step response represented by an nth-order lag transfer function (n is larger than 1) together with an internal gate resistor and an input capacitor between a gate terminal and an emitter terminal of the switching element, wherein
the switching element has wide-bandgap characteristics

2. The drive circuit for a switching element according to claim 1, wherein
an attenuation coefficient of the nth-order lag transfer function is not less than 0.7 and not more than 1.0.

3. The drive circuit for a switching element according to claim 1, wherein
the circuit having the step response represented by the nth-order lag transfer function (n is larger than 1)
reduces a peak value of a gate current of the switching element and
increases a gate current value in a miller period when compared to a circuit having a step response represented by a first-order lag transfer function.
